(19) United States
(12) Patent Application Publication
(10) Pub. No.: US 2025/0383389 A1
(43) Pub. Date: Dec. 18, 2025

(54) PRE-CHARGE CONTROLLER FOR HIGH VOLTAGE BATTERY APPLICATIONS

(71) Applicant: Analog Devices, Inc., Wilmington, MA (US)

(72) Inventors: Mudit KHANNA, Wilmington, MA (US); Pankaj KASHIKA, Wilmington, MA (US)

(21) Appl. No.: 19/241,040

(22) Filed: Jun. 17, 2025

Related U.S. Application Data
(60) Provisional application No. 63/660,878, filed on Jun. 17, 2024.

(51) Int. Cl. G01R 31/00; B60K 6/28; B60L 58/10; G01R 19/165; H03K 17/56

(52) U.S. Cl. CPC G01R 31/007; G01R 19/16576; H03K 17/56; B60K 6/28; B60L 58/10

(57) ABSTRACT

Example implementations include a method, apparatus and integrated circuit (IC) for pre-charging a battery system. The IC may include an isolated gate driver configured to drive a switching device for selectively coupling a high voltage battery to a load capacitor. The IC may further include an integrated isolated current sense amplifier configured to sense current flowing through the switching device during a pre-charge operation. The IC may further include a programmable current limit circuit configured to regulate the pre-charge current to a predetermined value. The IC may further include a charge completion detection circuit configured to identify when the pre-charge operation is complete based on the sensed current or voltage across the load capacitor. The IC may further include a fault detection circuit configured to detect one or more fault conditions.

### RELATED APPLICATIONS

This application claims the benefit of U.S. Patent Application Ser. No. 63/660,878, entitled “PRE-CHARGE CONTROLLER FOR HIGH VOLTAGE BATTERY APPLICATIONS” and filed on Jun. 17, 2024, which is assigned to the assignee hereof, and incorporated herein by reference in its entirety.

### TECHNICAL FIELD

Aspects of the present disclosure relate generally to a pre-charge controller for high voltage battery applications.

### BACKGROUND

The battery storage technology is increasing in its adoption across multiple industries ranging from electric cars to solar power. In all these high voltage battery systems, battery monitoring (BMS) integrated circuits (ICs) are used to protect regulate the cell balancing. Along with these BMS systems, relays and contactors are used as a protection device to disconnect the downstream loads. At the end of the battery pack, before the loads, a large capacitor is typically present to filter the noise from loads. During the start-up of the system, the contactors are closed to connect battery to the cap. However, without any resistance in the path, closing the contactors would cause a surge in current. In the current implementation, a resistor is used in series with a contactor to first pre-charge the bulk capacitor before turning ON the main relay. This method of charging the capacitor is slow, bulky and costly.

### SUMMARY

The following presents a simplified summary of one or more aspects to provide a basic understanding of such aspects. This summary is not an extensive overview of all contemplated aspects and is intended to neither identify key or critical elements of all aspects nor delineate the scope of any or all aspects. Its sole purpose is to present some concepts of one or more aspects in a simplified form as a prelude to the more detailed description that is presented later.

An example aspect includes integrated circuit (IC) for pre-charging a battery system. The IC may include an isolated gate driver configured to drive a switching device for selectively coupling a high voltage battery to a load capacitor. The IC may further include an integrated isolated current sense amplifier coupled to the switching device and configured to sense current flowing through the switching device during a pre-charge operation. The IC may further include a programmable current limit circuit coupled to the current sense amplifier and configured to regulate the pre-charge current to a predetermined value. The IC may further include a charge completion detection circuit configured to identify when the pre-charge operation is complete based on the sensed current or voltage across the load capacitor. The IC may further include a fault detection circuit configured to detect one or more fault conditions including at least one of gate open or short, desaturation of the switching device, undervoltage lockout, overcurrent, or thermal shutdown, and to provide a fault indication output.

Another example aspect includes an apparatus for pre-charging a battery system. The apparatus may include means for driving a switching device for selectively coupling a high voltage battery to a load capacitor. The apparatus may further include means for sensing current flowing through the switching device during a pre-charge operation. The apparatus may further include means for regulating the pre-charge current to a predetermined value. The apparatus may further include means for identifying when the pre-charge operation is complete based on the sensed current or voltage across the load capacitor. The apparatus may further include means for detecting one or more fault conditions including at least one of gate open or short, desaturation of the switching device, undervoltage lockout, overcurrent, or thermal shutdown, and to provide a fault indication output.

Another example aspect includes a method of pre-charging a battery system. The method may include driving a switching device for selectively coupling a high voltage battery to a load capacitor. The method may further include sensing current flowing through the switching device during a pre-charge operation. The method may further include regulating the pre-charge current to a predetermined value. The method may further include identifying when the pre-charge operation is complete based on the sensed current or voltage across the load capacitor. The method may further include detecting one or more fault conditions including at least one of gate open or short, desaturation of the switching device, undervoltage lockout, overcurrent, or thermal shutdown, and to provide a fault indication output.

To the accomplishment of the foregoing and related ends, the one or more aspects comprise the features hereinafter fully described and particularly pointed out in the claims. The following description and the annexed drawings set forth in detail certain illustrative features of the one or more aspects. These features are indicative, however, of but a few of the various ways in which the principles of various aspects may be employed, and this description is intended to include all such aspects and their equivalents.

### BRIEF DESCRIPTION OF THE DRAWINGS

The disclosed aspects will hereinafter be described in conjunction with the appended drawings, provided to illustrate and not to limit the disclosed aspects, wherein like designations denote like elements, and in which:

FIG. 1 is a circuit diagram for a pre-charging a battery system, in accordance with various implementations of the present disclosure;

FIG. 2 is a diagram of an example small outline integrated circuit, in accordance with various implementations of the present disclosure;

FIG. 3 is another circuit diagram for a pre-charging a battery system, in accordance with various implementation s of the present disclosure;

FIG. 4 is a further circuit diagram for a pre-charging a battery system, in accordance with various implementations of the present disclosure;

FIG. 5 is another circuit diagram for a pre-charging a battery system, in accordance with various implementations of the present disclosure; and

FIG. 6 is a flowchart of an example of pre-charging a battery system, in accordance with various implementations of the present disclosure.

### DETAILED DESCRIPTION

Aspects of the present disclosure are directed to a pre-charge controller for high voltage battery applications. Specifically, the present disclosure provides an isolated gate driver with a pre-charge controller for Automotive Safety Integrity Level B (ASIL-B) compliance. ASIL-B may represent a moderate level of risk and safety requirements for automotive electronic and electrical systems. In the context of high voltage battery systems and pre-charge controller integrated circuits (ICs), ASIL-B compliance may ensure that the device incorporates specific safety mechanisms and design features to mitigate risks associated with electrical faults, component failures, and hazardous operating conditions.

ASIL-B compliance in high voltage battery systems and pre-charge controller ICs may involve the integration of several safety and reliability features. To ensure reliable operation even in the presence of certain faults, redundant safety circuits such as precision bandgap references may be implemented. The device may incorporate dedicated fault indicators and diagnostic functions, which are beneficial for detecting and reporting abnormal conditions like overcurrent, undervoltage, or gate driver faults. Protection mechanisms may also be implemented, including overcurrent protection, thermal shutdown, undervoltage lockout (UVLO), and gate open or short detection, all of which may work together to prevent unsafe operation.

System monitoring may be achieved through the use of integrated current sense amplifiers and programmable current limits, allowing for precise control and supervision of the pre-charge and discharge processes to ensure safe and controlled energy transfer. High-voltage isolation between the control and power domains may be provided to protect low-voltage circuits and users from high-voltage hazards. Furthermore, ASIL-B compliance provides the ability to operate over a wide temperature range, typically from −40° C. to +150° C., to meet the stringent reliability and safety requirements of automotive applications. By incorporating these features, the pre-charge controller IC may be used in safety-critical automotive environments, such as electric and hybrid electric vehicle battery management systems, where moderate risk reduction measures are necessary to ensure functional safety and protect against potential hazards.

The present implementations set forth a pre-charge controller IC for high voltage battery applications, such as those found in electric and hybrid vehicles. The present implementations address the limitations of previous pre-charge techniques, which rely on bulky, slow, and costly resistor-based methods to pre-charge large capacitors present at the output of high voltage battery packs. In conventional systems, the sudden connection of the battery to the load capacitor can result in a large inrush current, potentially damaging system components. The disclosed pre-charge controller IC overcomes these drawbacks by employing a constant current control strategy in conjunction with an isolated gate driver, enabling efficient and controlled charging of the bulk capacitor in a buck-style switching configuration. This approach may significantly reduce the size, cost, and complexity of the pre-charge circuitry while improving system performance and reliability.

The pre-charge controller IC may integrate several advanced features to enhance safety, flexibility, and case of integration. For example, the pre-charge controller may include an isolated current sense amplifier for precise current control, programmable current limits to allow adjustable charge times, and internal or external charge completion detection. The device may be equipped with comprehensive safety protections, such as overcurrent protection, thermal shutdown, undervoltage lockout, and gate open/short detection, as well as optional Miller clamp protection. High-voltage isolation may be provided to safeguard low-voltage control circuits and users from high-voltage hazards. The IC may meet automotive safety standards, including ASIL B compliance and AEC-Q100 qualification, and is capable of operating over a wide temperature range. Additionally, the present implementations extend to discharging applications, where the same switching technique can be used to safely dissipate or transfer stored energy from the capacitor. By integrating these features into a single IC, the present implementations offer a cost-effective, compact, and robust solution for managing pre-charge and discharge operations in high voltage battery systems, providing significant advantages over existing technologies.

As such, the implementations set forth herein relate to an IC for pre-charging a battery system. The IC may include an isolated gate driver configured to drive a switching device for selectively coupling a high voltage battery to a load capacitor. The IC may further include an integrated isolated current sense amplifier coupled to the switching device and configured to sense current flowing through the switching device during a pre-charge operation. The IC may further include a programmable current limit circuit coupled to the current sense amplifier and configured to regulate the pre-charge current to a predetermined value. The IC may further include a charge completion detection circuit configured to identify when the pre-charge operation is complete based on the sensed current or voltage across the load capacitor. The IC may further include a fault detection circuit configured to detect one or more fault conditions including at least one of gate open or short, desaturation of the switching device, undervoltage lockout, overcurrent, or thermal shutdown, and to provide a fault indication output.

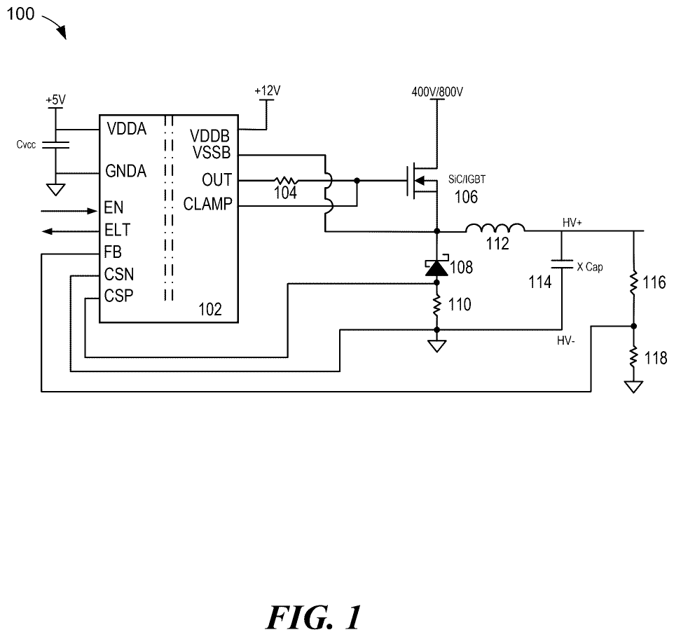

The described features will be presented in more detail below with reference to FIGS. 1-6.

FIG. 1 is a circuit diagram for a pre-charging a battery system 100. Specifically, the pre-charging battery system 100 sets forth pre-charging techniques for a large output capacitor (HVCAP) connected to a high voltage battery (400V/800V). The IC 102 may to control the charging current through a power switching device, which in this case may be a Silicon Carbide (SiC) or Insulated Gate Bipolar Transistor (IGBT) 106, providing efficient and safe pre-charging of the capacitor XCap 114. The SiC/IGBT transistor 106 may serve as the main switching element, enabling efficient and controlled charging of the capacitor by rapidly switching on and off under the direction of the gate driver output from the IC. This approach allows for precise current control, reduced power dissipation, and improved system reliability compared to traditional resistor-based pre-charge circuits.

The pre-charging a battery system 100 may further include a resistor 104 coupled or connected to the Out of IC 102. The pre-charging a battery system 100 may further include a Schottky diode 108, which may be configured to provide a fast, low-loss path for current during switching events, typically serving as a freewheeling or rectification diode to protect components and improve efficiency. The pre-charging a battery system 100 may further include an inductor 112, which may be configured to control and smooth the current flow during the pre-charging of the bulk capacitor at the output. The pre-charging a battery system 100 may further include a resistor 110 between the Schottky diode 108 and ground. The pre-charging a battery system 100 may further include resistors 116 and 118.

The pre-charge controller IC 102 may include a variety of pins, each serving a specific function within the circuit. The VDDA pin may be the primary analog supply voltage input, providing power to the analog circuitry within the IC. GNDA may be the analog ground reference, ensuring stable operation and noise immunity for sensitive analog signals. The EN (Enable) pin may be a digital input that allows the user to enable or disable the IC's operation, providing flexibility for system control and safety interlocks. The FLT (Fault) pin may be an output that indicates fault conditions, such as overcurrent, thermal shutdown, or gate driver errors, enabling the system to take protective action if necessary. The FB (Feedback) pin may be used to monitor the output voltage or current, allowing the controller to regulate the pre-charge process and ensure the capacitor is charged to the desired level.

The SiC/IGBT transistor 106 may act as the main power switch in the pre-charge path. The SiC/IGBT transistor's 106 gate may be driven by the OUT pin of the IC, while its source/emitter and drain/collector are connected in series between the high voltage battery and the output capacitor (HVCAP). When the IC 102 enables the gate drive, the transistor conducts, allowing controlled current to flow and charge the capacitor. The use of a SiC or IGBT device is particularly advantageous in high voltage, high current automotive applications due to their high efficiency, fast switching capability, and robustness under demanding conditions

During system start-up, the controller IC 102 enabled via the EN pin. The IC 102 may monitor the current through the CSP/CSN pins and regulates the gate of the SiC/IGBT transistor 106 via the OUT pin, ensuring that the pre-charge current does not exceed the programmed limit. The FB pin may provide feedback for voltage regulation, and the CLAMP pin ensures safe gate operation. If any fault is detected, the FLT pin may signal the system controller to take protective action. The isolation between the analog (VDDA/GNDA) and digital (VDDB/VSSB) domains ensures safe operation in high voltage environments.

The pre-charge controller IC 102 may incorporate an integrated isolated current sense amplifier, allowing for precise current control and a programmable current limit to tailor the pre-charge process to specific system requirements. It also provides internal or external options for detecting when charging is complete. Safety may be implemented, with features such as gate open/short indication, optional Miller clamp protection, undervoltage lockout (UVLO), overcurrent protection, thermal shutdown, and compliance with ASIL B automotive safety standards, including a dedicated fault indicator.

The pre-charge controller IC 102 may provide a number of benefits, specifically developed for high voltage battery systems commonly used in automotive applications such as electric and hybrid vehicles. The pre-charge controller IC 102 may integrate an isolated gate driver and a pre-charge controller within a compact SOIC (Wide Body) package, providing a robust and efficient solution for managing the initial charging of large capacitors at the output of high voltage battery packs. The pre-charge controller IC 102 may include a powerful N-channel gate driver capable of 2A peak source/sink current, a dedicated enable pin for flexible operation, and support for high switching frequencies up to 400 kHz. The device offers strong electrical isolation, withstanding 5kVRMS for 60 seconds and continuous operation at 848VRMS, as well as surge protection up to ±5 kV, ensuring safety in demanding automotive environments

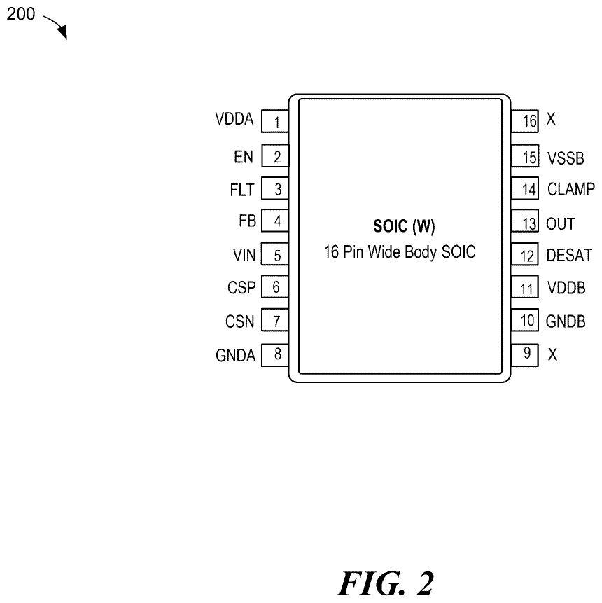

FIG. 2 is a diagram of an example small outline integrated circuit (SOIC) 200. The SOIC 200 corresponds to or may be integrated as part of a pre-charge controller IC for high voltage battery applications, such as those found in electric vehicles and hybrid electric vehicles. The SOIC 200 may integrate both an isolated gate driver and a pre-charge controller, providing robust control, protection, and isolation for managing the pre-charging of large bulk capacitors in high voltage battery systems. Each of the 16 pins on the SOIC 200 package may serve a distinct function within the overall circuit to ensure safe, efficient, and reliable operation in compliance with ASIL-B.

The VDDA pin may be the primary analog supply voltage input, delivering power to the analog and control circuitry within the IC. The EN (Enable) pin may be a digital input that allows the user to activate or deactivate the IC, providing a means for system-level control and safety interlocks. The FLT (Fault) pin may be an output that signals the presence of fault conditions, such as overcurrent, undervoltage, or thermal events, thereby enabling the system to respond appropriately to protect both the IC and the connected power components. The FB (Feedback) pin may be used to monitor the output voltage or current, allowing the controller to regulate the pre-charge process and ensure the bulk capacitor is charged to the correct level.

The VIN pin may be the main input voltage supply for the IC, powering the internal circuitry and supporting the operation of the gate driver and pre-charge controller. The CSP (Current Sense Positive) and CSN (Current Sense Negative) pins may be differential inputs connected across a current sense resistor or shunt, enabling precise measurement of the pre-charge current. This differential sensing capability may allow the IC to implement accurate current control and protection features. The GNDA pin may be the analog ground reference for the low voltage side of the IC, ensuring stable operation and minimizing noise interference for sensitive analog signals.

The two X pins labeled may be reserved for no-connect (NC) or future functionality. The VSSB pin may be the isolated ground reference for the high voltage side of the system, providing galvanic isolation between the low voltage control domain and the high voltage power domain, which is essential for safety and system integrity. The CLAMP pin may offer an optional Miller clamp function, which helps to prevent unintended turn-on of the external power switch (such as a SiC or IGBT transistor) due to voltage transients or capacitive coupling, thereby enhancing the robustness and safety of the system.

The OUT pin may be the gate driver output, which directly controls the gate of the external SiC or IGBT transistor, turning it on and off as required to regulate the pre-charge current flowing into the bulk capacitor. The DESAT pin may be used for desaturation detection, providing protection against short-circuit or overcurrent conditions in the external power switch by monitoring the voltage across the device and triggering a fault response if an abnormal condition is detected. The VDDB pin may be the secondary or isolated supply voltage input, supplying power to the gate driver and other isolated circuitry on the high voltage side of the IC. The GNDB pin may service as the ground reference for the high voltage side, complementing VSSB and ensuring proper operation of the isolated circuitry. As such, the SOIC 200 may be used as a pre-charge controller IC to deliver control, protection, and isolation in high voltage battery systems.

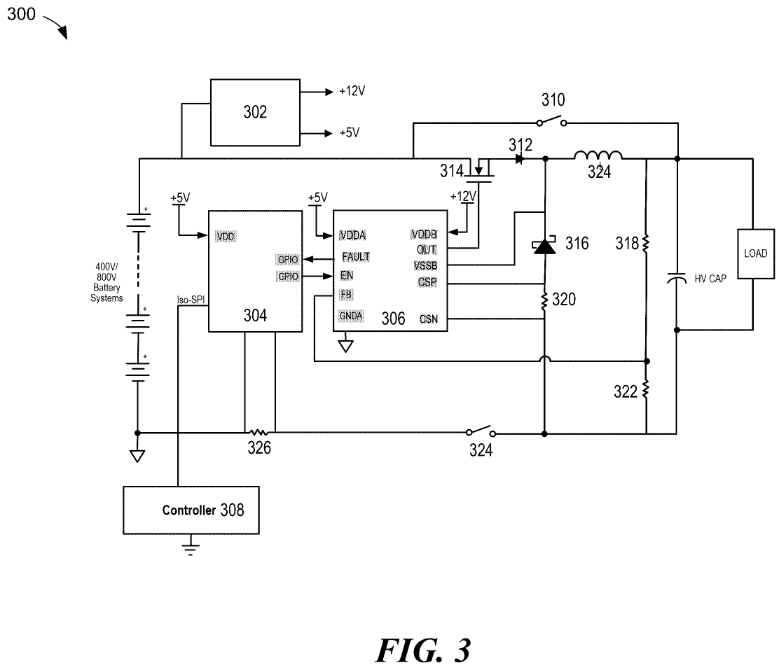

FIG. 3 is another circuit diagram for a pre-charging a battery system 300. The pre-charging a battery system 300 includes the integration of two key ICs within a high voltage battery pre-charge and monitoring system, a high voltage battery, i.e., 400V/800V battery systems, a bulk capacitor, and associated passive and switching elements. The first IC 304 and the second 306 may be equipped with a set of specialized pins, each serving a distinct function to ensure safe, efficient, and reliable operation of the pre-charge controller and battery management system.

The pre-charging a battery system 300 may include a microcontroller or a battery management system (BMS) interface device 302 to allow direct 400V/800V to 12V conversion. The pre-charging a battery system 300 may include a 326 connected to the first IC 304, a switch 324, and a controller 308 connected to ground. The pre-charging a battery system 300 may include switch 310, diode 312, transistor 314, a Schottky diode 316, resistors 318, 320, 322, and an inductor 324.

The first IC 304, which may be a microcontroller or a BMS interface device, may include a VDD pin and two GPIO (General Purpose Input/Output) pins. The VDD pin may serve as the primary power supply input for the IC, providing the necessary voltage to power the internal logic and control circuits. This pin may be useful for the operation of the IC, ensuring that all digital and analog functions receive stable and regulated power. The two GPIO pins are digital input/output terminals that can be configured by the user or system designer for a variety of control and monitoring tasks.

In the context of the pre-charge controller system, these GPIO pins may be used to send control signals to the pre-charge controller IC, receive status or fault indications, or interface with other system components such as relays, contactors, or communication buses. The flexibility of the GPIO pins allows for integration with the broader battery management and vehicle control architecture. The first IC 304 may also be connected to the controller 308 via an isolated serial peripheral interface (ISO-SPI) communication link, and can communicate faults and other critical information to the microcontroller.

The second IC 306 may be the pre-charge controller with an integrated isolated gate driver to provide control, sensing, and protection functions. The VDDA pin may be the analog supply voltage input, delivering regulated power to the analog and control sections of the IC, thereby ensuring stable operation of sensitive analog circuitry. The FAULT pin may be a dedicated output that signals the presence of fault conditions, such as overcurrent, undervoltage, or thermal anomalies, enabling the system to take protective action or alert the user to abnormal operating states. The EN pin may be a digital input that allows the system to activate or deactivate the pre-charge controller, providing a critical safety interlock and facilitating system-level control over the pre-charge process.

The second IC 306, which may correspond to the pre-charge controller, may use a constant current control loop to charge the bulk capacitor. This is achieved by regulating a power switch (such as a MOSFET) via the isolated gate driver. The integrated current sense amplifier monitors the current flowing into the capacitor, ensuring it does not exceed the programmable limit. The controller can be configured for different charge times and current limits depending on the system requirements (e.g., 3A RMS for a 400V battery and 1500 uF cap results in a charge time of about 200 ms.

The FB pin may be used to monitor the output voltage or current, allowing the controller to regulate the pre-charge process and ensure that the bulk capacitor is charged to the desired level without exceeding safe operating limits. The GNDA pin may serve as the analog ground reference for the low voltage side of the IC, providing a stable and noise-free ground for sensitive analog and control signals. The VDDB pin may be the isolated supply voltage input for the high voltage side of the IC, powering the gate driver and other isolated circuitry that interface directly with the high voltage battery and switching devices.

The OUT pin may be the gate driver output, which is connected to the gate of an external power switch, such as a silicon carbide (SiC) or insulated-gate bipolar transistor (IGBT). This pin delivers the necessary drive signals to turn the external switch on and off, thereby controlling the flow of pre-charge current into the bulk capacitor. The VSSB pin may be the isolated ground reference for the high voltage side, ensuring galvanic isolation between the low voltage control domain and the high voltage power domain, which may be essential for both safety and system integrity. The CSP and CSN pins may be differential inputs connected across a current sense resistor or shunt. These pins enable precise measurement of the pre-charge current, allowing the IC to implement accurate current control, protection, and monitoring features.

The pre-charging a battery system 300 includes a 2A peak source/sink N-channel gate driver, a dedicated enable (EN) pin for flexibility, and support for switching frequencies up to 400 kHz. The pre-charging a battery system 300 provides a high-voltage isolation, withstanding 5kVRMS for 60 seconds and continuous operation at 848VRMS, as well as surge protection up to ±5 kV. The pre-charge controller (i.e., second IC 306) may incorporate an integrated isolated current sense amplifier for precise current control, a programmable current limit to adjust charge time, and both internal and external options for charge completion detection. Safety may be further enhanced with gate open/short detection, optional Miller clamp protection, undervoltage lockout (UVLO), overcurrent protection, thermal shutdown, and compliance with ASIL B safety standards, including a redundant bandgap reference and a dedicated fault indicator.

The pre-charge controller may be designed to communicate faults to a microcontroller via the Iso-SPI interface and uses low-side current sensing for case of control. Charge time estimation may be provided for typical automotive scenarios: with a 3A RMS charging current, a 400V battery and a 1500 μF capacitor can be pre-charged in approximately 200 milliseconds, while an 800V battery with a 2500 μF capacitor requires about 667 milliseconds. The system may allow for higher charging currents if faster charge times are needed, and the same switching technique can be applied for controlled discharging of the capacitor, either by dissipating energy through a resistor or transferring it to another storage element.

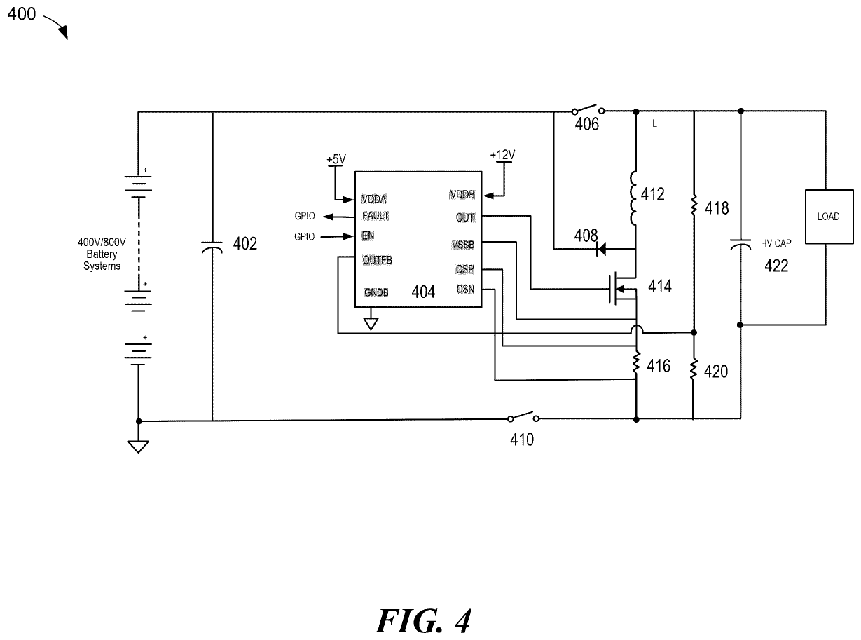

FIG. 4 is a further circuit diagram for a pre-charging a battery system 400 associated with a discharging application. The pre-charging a battery system 400 may include at least a non-polarized capacitor 402, a pre-charge IC controller 404, switch 406, diode 408, switch 410, inductor 412, transistor 414, resistors 416, 418, and 420, alone with an HV cap 422.

The pre-charging a battery system 400, which may corresponds to a discharging application circuit may safely and efficiently discharge the large capacitor found at the output of high voltage battery systems in automotive applications. This pre-charging a battery system 400 may leverage the pre-charge controller IC 404 used for charging and manage the controlled release of stored energy from the capacitor, either by dissipating it or transferring it to another storage element.

The pre-charging a battery system 400 includes a high voltage capacitor (HVCAP), which is connected across the high voltage battery output, for example, at 400V or 800V. The HVCAP may store a significant amount of energy and requires a controlled discharge process to prevent potential damage to downstream components and to ensure safety during maintenance or system shutdown. The pre-charge/discharge controller may serve as the core component, integrating an isolated gate driver, a current sense amplifier, and a programmable current limit. This controller manages a switching element, such as a MOSFET, which may be responsible for connecting the HVCAP to the discharge path. The switching element is controlled by the gate driver within the pre-charge IC controller 404, which can turn the switch on or off based on programmed logic and real-time current sensing.

A current sense resistor is placed in the discharge path, allowing the controller to monitor the discharge current through its integrated current sense amplifier. This ensures that the current remains within safe, programmable limits. The energy from the HVCAP can be directed either to a resistive load, where it is dissipated as heat, or to another capacitor or battery, where it can be reused. In the resistive discharge mode, the controller enables the switching element, allowing the HVCAP to discharge through a resistor. The pre-charge IC controller 404 may monitor the current and can terminate the discharge once the voltage across the capacitor drops below a safe threshold or after a predetermined time, ensuring a controlled and safe release of energy. Alternatively, in the energy transfer mode, the circuit is configured to transfer the stored energy from the HVCAP to another storage device. The controller may manage the switching to direct current flow into the secondary storage, stopping the discharge once the output voltage falls below a safe level to prevent over-discharge.

The circuit offers several programmable and safety features. The programmable peak current limit allows users to set a maximum discharge current, which helps control the discharge time and prevents excessive current that could damage system components. The pre-charge IC controller 404 may also provide real-time fault monitoring, including overcurrent protection, thermal shutdown, and gate open or short detection. Faults may be communicated to the system microcontroller via a dedicated FAULT pin or through the Iso-SPI interface. Additionally, the circuit maintains high voltage isolation between the control and power domains, ensuring both user and system safety during discharge operations.

The discharging application circuit provides a flexible, programmable, and safe method for managing the energy stored in high voltage capacitors. By utilizing the same controller IC for both charging and discharging, the system benefits from reduced complexity and cost. The ability to either dissipate or reuse stored energy adds versatility, while the integrated safety features and precise current control enhance reliability and protect both the system and personnel.

In an aspect, the pre-charging a battery system 400 may facilitate discharge the capacitor in at least one of two ways. In one implementation, the energy stored at the capacitor may be dissipated across a resistor. Specifically, an IC element and/or resistive component may be used to enable/disable a high voltage switch. In a second implementation, the energy in the capacitor may be reused and transferred to another capacitor or battery. Specifically, a circuit element may be used to transfer the energy from the capacitor to another capacitor or battery. The pre-charging a battery system 400 may Turn OFF discharging after Output voltage falls below the safe levels. Further, a programmable peak current limit to control maximum discharge current and discharge time.

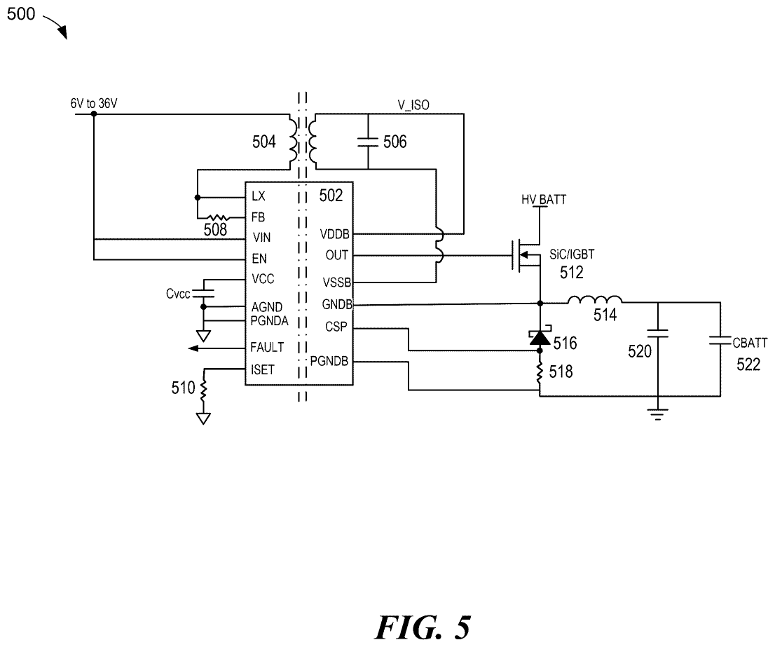

FIG. 5 is another circuit diagram for a pre-charging a battery system 500. The pre-charging a battery system 500 may include two inductors 504 for inductive coupling, resistors 508, 510, 518, capacitor 506, SiC/IGBT 512, inductor 514, Schottky diode 516, capacitor 520 and a CBATT capacitor 522. The pre-charging a battery system 500 includes a pre-charge controller IC 502, which may be for high voltage battery applications in automotive systems. The pre-charge controller IC 502 corresponds to a multi-pin SOIC package, and each pin is connected to specific circuit elements to facilitate safe, efficient, and programmable pre-charging of a bulk capacitor within a high voltage battery system

The LX pin may serve as the switching node for the internal or external power MOSFET. It is the main switching point in the buck-style converter topology used in the pre-charge circuit, alternating between high and low voltage as the MOSFET turns on and off. This switching action enables energy transfer from the high voltage battery to the bulk capacitor. The FB (feedback) pin is connected to a voltage divider network that samples the output voltage across the bulk capacitor.

The VIN pin receives the primary side supply voltage, typically sourced from a low voltage rail such as 6V to 36V. This input powers the control and gate drive circuitry within the IC, providing the necessary energy for its operation. The EN (enable) pin is connected to a microcontroller or system logic, allowing the system to enable or disable the pre-charge controller as needed. When the EN pin is asserted, the IC initiates the pre-charge sequence; when de-asserted, the IC enters a low-power or shutdown state.

The VCC pin may be connected to a regulated supply voltage, often derived from VIN, and provides power to the analog and digital sections of the controller, ensuring stable operation of the IC's internal circuits. AGND (analog ground) serves as the ground reference for the analog circuitry within the IC and is typically connected to the system's analog ground plane to minimize noise and ensure accurate signal processing. PGNDA (power ground A) is the power ground for the primary side of the IC, associated with the high current paths of the controller, and is connected to the system's power ground to provide a low impedance return path for switching currents.

The FAULT pin may be an output connected to system diagnostics or a microcontroller. It signals fault conditions such as overcurrent, undervoltage, or thermal shutdown, enabling the system to take protective action. The ISET pin may be connected to an external resistor that programs the peak current limit for the pre-charge process. By adjusting the value of this resistor, the maximum allowable pre-charge current can be set to match system requirements and ensure safe operation.

VDDB may be the secondary side supply voltage pin, powering the gate driver and other secondary side circuits while maintaining galvanic isolation between the high voltage and control domains. The OUT pin is connected to the gate of an external N-channel MOSFET and delivers the gate drive signal, turning the MOSFET on and off to control the flow of pre-charge current into the bulk capacitor. VSSB and GNDB may serve as ground references for the secondary side, ensuring proper operation of the isolated gate driver and related circuits, and providing a return path for secondary side currents while maintaining isolation integrity.

The CSP (current sense positive) pin may be connected to the positive side of a low-side current sense resistor placed between the MOSFET source and ground. This pin, together with its complement (typically CSN), allows the IC to monitor the pre-charge current with high accuracy. PGNDB (power ground B) may be the power ground for the secondary side, associated with the high current paths of the gate driver and output stage, and is connected to the secondary side ground plane to ensure robust operation of the gate drive circuitry.

As the OUT pin of the pre-charge controller IC 502 is connected to a SiC (Silicon Carbide) or IGBT (Insulated Gate Bipolar Transistor), it is configured to control the switching of this external power transistor. The OUT pin may serve as the gate drive output, delivering the necessary voltage and current to turn the SiC/IGBT on and off according to the pre-charge controller's logic and timing. In the context of high voltage battery systems, the SiC/IGBT acts as the main switching element in the pre-charge circuit. Its primary function is to regulate the flow of current from the high voltage battery to the bulk capacitor during the pre-charge phase.

The pre-charge controller IC 502 uses the OUT pin to precisely control the gate of the SiC/IGBT. When the OUT pin drives the gate high (for an N-channel device), the pre-charge controller IC 502 may be configured to turn on the SiC/IGBT, allowing current to flow from the battery to the capacitor. When the OUT pin drives the gate low (for an N-channel device), the pre-charge controller IC 502 may be configured to turn off SiC/IGBT, allowing current to flow from the battery to the capacitor.

The pre-charge controller IC 502 offers a number of benefits for high voltage battery systems, particularly in automotive and industrial applications. At its core, the pre-charge controller IC 502 integrates an isolated gate driver capable of efficiently driving high-performance power transistors such as Silicon Carbide (SiC) or Insulated Gate Bipolar Transistor (IGBT) devices. This isolation may be beneficial for safety, providing robust protection between the control circuitry and the high voltage battery system. The gate driver delivers up to 2A peak source and sink current, ensuring fast and reliable switching of external power devices.

The pre-charge controller IC 502 offers high voltage isolation, with the ability to endure up to 5kVRMS for 60 seconds and continuous operation at 848VRMS. The pre-charge controller IC 502 may also be configured to to handle ±5 kV surges between ground domains, which may be beneficial for automotive and industrial systems where high voltage transients are common. The integrated pre-charge controller may include a built-in isolated current sense amplifier, allowing for precise current control during the pre-charge phase. This ensures that the bulk capacitor may be charged both safely and efficiently. The controller supports programmable current limits, enabling users to adjust charge times to meet specific system requirements.

To further enhance safety and reliability, the pre-charge controller IC 502 may include internal charge complete detection, with the flexibility to implement external detection if needed. Such implementation may ensure that the pre-charge process is terminated at the appropriate time, preventing overcharging and reducing stress on system components. The pre-charge controller IC 502 may be include safety protections, including gate open/short indication to detect faults in the external power transistor, optional Miller clamp protection to prevent unintended turn-on due to voltage transients, under-voltage lockout (UVLO) protection to ensure operation only within safe voltage ranges, and both overcurrent protection and thermal shutdown to safeguard against excessive current or overheating. A dedicated FAULT indicator pin provides system-level fault reporting, and the IC may be compliant with ASIL B, including a precision redundant bandgap reference for safety-critical applications.

Automotive-grade reliability may be implemented to allow operation over a wide temperature range from −40° C. to +150° C., making the pre-charge controller IC 502 suitable for the most demanding environments. The pre-charge controller IC 502 may be configured for flexible system integration, supporting communication with battery management systems (BMS) via interfaces such as Iso-SPI, and is compatible with both 5V and 12V logic levels to accommodate a variety of microcontrollers and system voltages.

By replacing traditional resistor-based pre-charge circuits with an active, switch-mode approach, the IC reduces both the size and cost of the pre-charge circuitry. The integration of the gate driver, current sense, and control logic into a single package minimizes the need for external components. Performance and efficiency may be improved through the use of a constant current controller and high-speed gate driver, which enable faster and more efficient charging of the bulk capacitor, reducing pre-charge time and energy losses. Safety may be enhanced via protection features, which ensure that the pre-charge process is conducted safely and that faults are detected and addressed immediately, protecting both the battery and downstream electronics from damage.

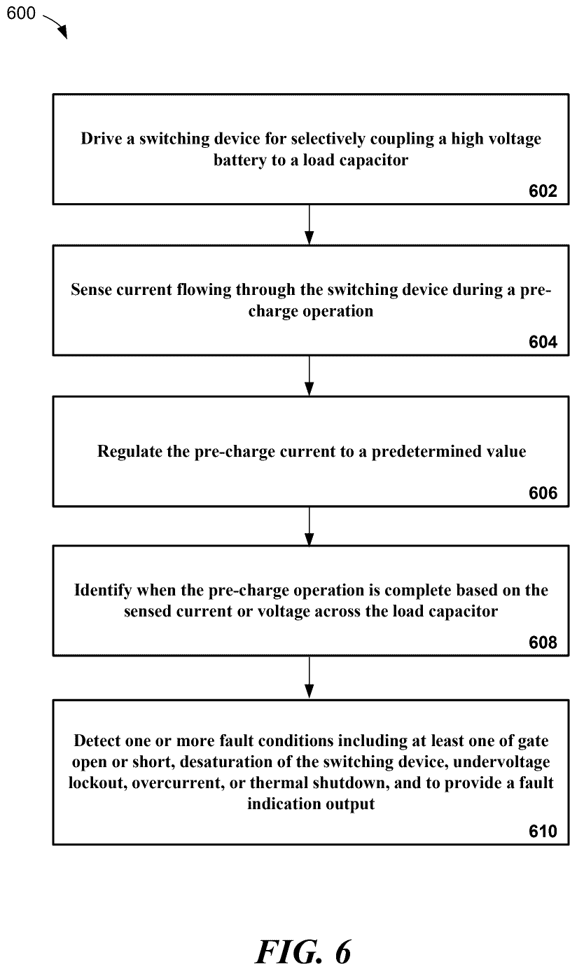

FIG. 6 is a flowchart of an example of pre-charging a battery system. Specifically, the flow chart sets forth an example of a method 600 for pre-charging a battery system, such as in pre-charging battery system 100, 200, 300, 400 and 500. In an example, the pre-charging battery system can perform the functions described in method 600 using one or more of the components and techniques described in FIGS. 1-5, such as via execution of one or more components described herein, individually or in combination

At block 602, the method 600 may drive a switching device for selectively coupling a high voltage battery to a load capacitor. In an aspect, the pre-charging a battery system 100, 300, 400, and/or 500, e.g., in conjunction with the pre-charge controller IC 102, 200, 306, 404, and/or 502 may be configured to drive a switching device for selectively coupling a high voltage battery to a load capacitor. Thus, the pre-charging a battery system 100, 300, 400, and/or 500, or one of its subcomponents may define the means for driving a switching device for selectively coupling a high voltage battery to a load capacitor.

At block 604, the method 600 may sense current flowing through the switching device during a pre-charge operation. In an aspect, the pre-charging a battery system 100, 300, 400, and/or 500, e.g., in conjunction with the pre-charge controller IC 102, 200, 306, 404, and/or 502 may be configured to sense current flowing through the switching device during a pre-charge operation. Thus, the pre-charging a battery system 100, 300, 400, and/or 500, or one of its subcomponents may define the means for sensing current flowing through the switching device during a pre-charge operation.

At block 606, the method 600 may regulate the pre-charge current to a predetermined value. In an aspect, the pre-charging a battery system 100, 300, 400, and/or 500, e.g., in conjunction with the pre-charge controller IC 102, 200, 306, 404, and/or 502 may be configured to regulate the pre-charge current to a predetermined value. Thus, the pre-charging a battery system 100, 300, 400, and/or 500, or one of its subcomponents may define the means for regulating the pre-charge current to a predetermined value.

At block 606, the method 600 may identify when the pre-charge operation is complete based on the sensed current or voltage across the load capacitor. In an aspect, the pre-charging a battery system 100, 300, 400, and/or 500, e.g., in conjunction with the pre-charge controller IC 102, 200, 306, 404, and/or 502 may be configured to identify when the pre-charge operation is complete based on the sensed current or voltage across the load capacitor. Thus, the pre-charging a battery system 100, 300, 400, and/or 500, or one of its subcomponents may define the means for identifying when the pre-charge operation is complete based on the sensed current or voltage across the load capacitor.

At block 608, the method 600 may detect one or more fault conditions including at least one of gate open or short, desaturation of the switching device, undervoltage lockout, overcurrent, or thermal shutdown, and to provide a fault indication output. In an aspect, the pre-charging a battery system 100, 300, 400, and/or 500, e.g., in conjunction with the pre-charge controller IC 102, 200, 306, 404, and/or 502 may be configured to detect one or more fault conditions including at least one of gate open or short, desaturation of the switching device, undervoltage lockout, overcurrent, or thermal shutdown, and to provide a fault indication output. Thus, the pre-charging a battery system 100, 300, 400, and/or 500, or one of its subcomponents may define the means for detecting one or more fault conditions including at least one of gate open or short, desaturation of the switching device, undervoltage lockout, overcurrent, or thermal shutdown, and to provide a fault indication output.

In some implementations, the isolated gate driver may be further configured to provide a peak source or sink current of at least 2A to the switching device. In some implementations, the isolated gate driver may be further configured to operate at a switching frequency up to 400 kHz. In some implementations, the isolated gate driver may be implemented in a wide body integrated circuit package capable of withstanding an isolation voltage value for a defined period.

In some implementations, the integrated isolated current sense amplifier may be further configured to provide feedback for closed-loop current regulation during the pre-charge operation. In some implementations, the programmable current limit circuit may include a user-programmable input for setting the pre-charge current limit. In some implementations, the programmable current limit circuit may be further configured to adjust the pre-charge current to accommodate a different battery system voltage or load capacitance.

In some implementations, the charge completion detection circuit may be further configured to detect completion of the pre-charge operation based on the current sensed by the current sense amplifier falling below a predetermined threshold. In some implementations, the charge completion detection circuit may be further configured to detect completion of the pre-charge operation based on the voltage across the load capacitor reaching a predetermined value. In some implementations, the charge completion detection circuit may include an internal detection circuit or external detection circuit for charge completion detection.

In some implementations, the fault detection circuit may be further configured to provide a dedicated fault indicator output pin. In some implementations, the fault detection circuit may be further configured to detect a Miller clamp fault condition. In some implementations, the fault detection circuit may be further configured to detect undervoltage lockout on an input supply voltage. In some implementations, the fault detection circuit may be further configured to detect overcurrent conditions during the pre-charge operation.

In some implementations, the fault detection circuit may be further configured to detect at least one thermal shutdown condition when the integrated circuit temperature exceeds a predetermined threshold. In some implementations, the integrated circuit may be associated with Automotive Safety Integrity Level B (ASIL B). In some implementations, the integrated circuit may be configured for use in an electric vehicle or hybrid electric vehicle high voltage battery system. In some implementations, the pre-charging a battery system may include an isolated communication interface configured to transmit fault or status information to an external microcontroller.

The above detailed description set forth above in connection with the appended drawings describes examples and does not represent the only examples that may be implemented or that are within the scope of the claims. The term “example,” when used in this description, means “serving as an example, instance, or illustration,” and not “preferred” or “advantageous over other examples.” The detailed description includes specific details for the purpose of providing an understanding of the described techniques. These techniques, however, may be practiced without these specific details. In some instances, well-known structures and apparatuses are shown in block diagram form in order to avoid obscuring the concepts of the described examples.

The terms “connected,” “coupled,” or any variant thereof, mean any connection or coupling, either direct or indirect, between two or more elements, and may encompass the presence of one or more intermediate elements between two elements that are “connected” or “coupled” together. The coupling or connection between the elements may be physical, logical, or a combination thereof. As used herein, two elements may be considered to be “connected” or “coupled” together by the use of one or more wires, cables and/or printed electrical connections, as well as by the use of electromagnetic energy, such as electromagnetic energy having wavelengths in the radio frequency region, the microwave region and the optical (both visible and invisible) region, as several non-limiting and non-exhaustive examples.

Various aspects of the disclosure may take the form of an entirely or partially hardware aspect, an entirely or partially software aspect, or a combination of software and hardware. Furthermore, as described herein, various aspects of the disclosure (e.g., systems and methods) may take the form of a computer program product comprising a computer-readable non-transitory storage medium having computer-accessible instructions (e.g., computer-readable and/or computer-executable instructions) such as computer software, encoded or otherwise embodied in such storage medium. Those instructions can be read or otherwise accessed and executed by one or more processors to perform or permit the performance of the operations described herein. The instructions can be provided in any suitable form, such as source code, compiled code, interpreted code, executable code, static code, dynamic code, assembler code, combinations of the foregoing, and the like. Any suitable computer-readable non-transitory storage medium may be utilized to form the computer program product. For instance, the computer-readable medium may include any tangible non-transitory medium for storing information in a form readable or otherwise accessible by one or more computers or processor(s) functionally coupled thereto. Non-transitory storage media can include read-only memory (ROM); random access memory (RAM); magnetic disk storage media; optical storage media; flash memory, and so forth.

Aspects of this disclosure are described herein with reference to block diagrams and flowchart illustrations of methods, systems, apparatuses, and computer program products. It can be understood that each block of the block diagrams and flowchart illustrations, and combinations of blocks in the block diagrams and flowchart illustrations, respectively, can be implemented by computer-accessible instructions. In certain implementations, the computer-accessible instructions may be loaded or otherwise incorporated into a general-purpose computer, a special-purpose computer, or another programmable information processing apparatus to produce a particular machine, such that the operations or functions specified in the flowchart block or blocks can be implemented in response to execution at the computer or processing apparatus.

Unless otherwise expressly stated, it is in no way intended that any protocol, procedure, process, or method set forth herein be construed as requiring that its acts or steps be performed in a specific order. Accordingly, where a process or method claim does not actually recite an order to be followed by its acts or steps, or it is not otherwise specifically recited in the claims or descriptions of the subject disclosure that the steps are to be limited to a specific order, it is in no way intended that an order be inferred, in any respect. This holds for any possible non-express basis for interpretation, including: matters of logic with respect to the arrangement of steps or operational flow; plain meaning derived from grammatical organization or punctuation; the number or type of aspects described in the specification or annexed drawings; or the like.

As used in this disclosure, including the annexed drawings, the terms “component,” “module,” “system,” and the like are intended to refer to a computer-related entity or an entity related to an apparatus with one or more specific functionalities. The entity can be either hardware, a combination of hardware and software, software, or software in execution. One or more of such entities are also referred to as “functional elements.” As an example, a component can be a process running on a processor, a processor, an object, an executable, a thread of execution, a program, and/or a computer. For example, both an application running on a server or network controller, and the server or network controller can be a component. One or more components can reside within a process and/or thread of execution and a component can be localized on one computer and/or distributed between two or more computers. Also, these components can execute from various computer readable media having various data structures stored thereon. The components can communicate via local and/or remote processes such as in accordance with a signal having one or more data packets (e.g., data from one component interacting with another component in a local system, distributed system, and/or across a network such as the Internet with other systems via the signal). As another example, a component can be an apparatus with specific functionality provided by mechanical parts operated by electric or electronic circuitry, which parts can be controlled or otherwise operated by program code executed by a processor. As yet another example, a component can be an apparatus that provides specific functionality through electronic components without mechanical parts, the electronic components can include a processor to execute program code that provides, at least partially, the functionality of the electronic components. As still another example, interface(s) can include I/O components or Application Programming Interface (API) components. While the foregoing examples are directed to aspects of a component, the exemplified aspects or features also apply to a system, module, and similar.

In addition, the term “or” is intended to mean an inclusive “or” rather than an exclusive “or.” That is, unless specified otherwise, or clear from context, “X employs A or B” is intended to mean any of the natural inclusive permutations. That is, if X employs A; X employs B; or X employs both A and B, then “X employs A or B” is satisfied under any of the foregoing instances. Moreover, articles “a” and “an” as used in this specification and annexed drawings should be construed to mean “one or more” unless specified otherwise or clear from context to be directed to a singular form.

In addition, the terms “example” and “such as” and “e.g.” are utilized herein to mean serving as an instance or illustration. Any aspect or design described herein as an “example” or referred to in connection with a “such as” clause or “e.g.” is not necessarily to be construed as preferred or advantageous over other aspects or designs described herein. Rather, use of the terms “example” or “such as” or “e.g.” is intended to present concepts in a concrete fashion. The terms “first,” “second,” “third,” and so forth, as used in the claims and description, unless otherwise clear by context, is for clarity only and does not necessarily indicate or imply any order in time or space.

The term “processor,” as utilized in this disclosure, can refer to any computing processing unit or device comprising processing circuitry that can operate on data and/or signaling. A computing processing unit or device can include, for example, single-core processors; single-processors with software multithread execution capability; multi-core processors; multi-core processors with software multithread execution capability; multi-core processors with hardware multithread technology; parallel platforms; and parallel platforms with distributed shared memory. Additionally, a processor can include an integrated circuit, an application specific integrated circuit (ASIC), a digital signal processor (DSP), a field programmable gate array (FPGA), a programmable logic controller (PLC), a complex programmable logic device (CPLD), a discrete gate or transistor logic, discrete hardware components, or any combination thereof designed to perform the functions described herein. In some cases, processors can exploit nano-scale architectures, such as molecular and quantum-dot based transistors, switches and gates, in order to optimize space usage or enhance performance of user equipment. A processor may also be implemented as a combination of computing processing units.

In addition, terms such as “store,” “data store,” data storage,” “database,” and substantially any other information storage component relevant to operation and functionality of a component, refer to “memory components,” or entities embodied in a “memory” or components comprising the memory. It will be appreciated that the memory components described herein can be either volatile memory or nonvolatile memory, or can include both volatile and nonvolatile memory. Moreover, a memory component can be removable or affixed to a functional element (e.g., device, server).

Simply as an illustration, nonvolatile memory can include read only memory (ROM), programmable ROM (PROM), electrically programmable ROM (EPROM), electrically erasable ROM (EEPROM), or flash memory. Volatile memory can include random access memory (RAM), which acts as external cache memory. By way of illustration and not limitation, RAM is available in many forms such as synchronous RAM (SRAM), dynamic RAM (DRAM), synchronous DRAM (SDRAM), double data rate SDRAM (DDR SDRAM), enhanced SDRAM (ESDRAM), Synchlink DRAM (SLDRAM), and direct Rambus RAM (DRRAM). Additionally, the disclosed memory components of systems or methods herein are intended to comprise, without being limited to comprising, these and any other suitable types of memory.

Various aspects described herein can be implemented as a method, apparatus, or article of manufacture using special programming as described herein. In addition, various of the aspects disclosed herein also can be implemented by means of program modules or other types of computer program instructions specially configured as described herein and stored in a memory device and executed individually or in combination by one or more processors, or other combination of hardware and software, or hardware and firmware. Such specially configured program modules or computer program instructions, as described herein, can be loaded onto a general-purpose computer, a special-purpose computer, or another type of programmable data processing apparatus to produce a machine, such that the instructions which execute on the computer or other programmable data processing apparatus create a means for implementing the functionality of disclosed herein.

The term “article of manufacture” as used herein is intended to encompass a computer program accessible from any non-transitory computer-readable device, carrier, or media. For example, computer readable media can include but are not limited to magnetic storage devices (e.g., hard drive disk, floppy disk, magnetic strips, or similar), optical discs (e.g., compact disc (CD), digital versatile disc (DVD), blu-ray disc (BD), or similar), smart cards, and flash memory devices (e.g., card, stick, key drive, or similar).

The detailed description set forth herein in connection with the annexed figures is intended as a description of various configurations or implementations and is not intended to represent the only configurations or implementations in which the concepts described herein may be practiced. The detailed description includes specific details for the purpose of providing a thorough understanding of various concepts. However, it will be apparent to those skilled in the art that these concepts may be practiced without these specific details or with variations of these specific details. In some instances, well-known components are shown in block diagram form, while some blocks may be representative of one or more well-known components.

The previous description of the disclosure is provided to enable a person skilled in the art to make or use the disclosure. Various modifications to the disclosure will be readily apparent to those skilled in the art, and the common principles defined herein may be applied to other variations without departing from the scope of the disclosure. Furthermore, although elements of the described aspects may be described or claimed in the singular, the plural is contemplated unless limitation to the singular is explicitly stated. Additionally, all or a portion of any aspect may be utilized with all or a portion of any other aspect, unless stated otherwise. Thus, the disclosure is not to be limited to the examples and designs described herein but is to be accorded the widest scope consistent with the principles and novel features disclosed herein.

What is claimed is:

1. An integrated circuit for pre-charging a battery system, comprising:
an isolated gate driver configured to drive a switching device for selectively coupling a high voltage battery to a load capacitor;
an integrated isolated current sense amplifier coupled to the switching device and configured to sense current flowing through the switching device during a pre-charge operation;
a programmable current limit circuit coupled to the current sense amplifier and configured to regulate the pre-charge current to a predetermined value;
a charge completion detection circuit configured to identify when the pre-charge operation is complete based on the sensed current or voltage across the load capacitor; and
a fault detection circuit configured to detect one or more fault conditions including at least one of gate open or short, desaturation of the switching device, undervoltage lockout, overcurrent, or thermal shutdown, and to provide a fault indication output.

2. The integrated circuit of claim 1, wherein the isolated gate driver is further configured to provide a peak source or sink current of at least 2A to the switching device.

3. The integrated circuit of claim 1, wherein the isolated gate driver is further configured to operate at a switching frequency up to 400 kHz.

4. The integrated circuit of claim 1, wherein the isolated gate driver is implemented in a wide body integrated circuit package capable of withstanding an isolation voltage value for a defined period.

5. The integrated circuit of claim 1, wherein the integrated isolated current sense amplifier is further configured to provide feedback for closed-loop current regulation during the pre-charge operation.

6. The integrated circuit of claim 1, wherein the programmable current limit circuit includes a user-programmable input for setting the pre-charge current limit.

7. The integrated circuit of claim 1, wherein the programmable current limit circuit is further configured to adjust the pre-charge current to accommodate a different battery system voltage or load capacitance.

8. The integrated circuit of claim 1, wherein the charge completion detection circuit is further configured to detect completion of the pre-charge operation based on the current sensed by the current sense amplifier falling below a predetermined threshold.

9. The integrated circuit of claim 1, wherein the charge completion detection circuit is further configured to detect completion of the pre-charge operation based on the voltage across the load capacitor reaching a predetermined value.

10. The integrated circuit of claim 1, wherein the charge completion detection circuit includes an internal detection circuit or external detection circuit for charge completion detection.

11. The integrated circuit of claim 1, wherein the fault detection circuit is further configured to provide a dedicated fault indicator output pin.

12. The integrated circuit of claim 1, wherein the fault detection circuit is further configured to detect a Miller clamp fault condition.

13. The integrated circuit of claim 1, wherein the fault detection circuit is further configured to detect undervoltage lockout on an input supply voltage.

14. The integrated circuit of claim 1, wherein the fault detection circuit is further configured to detect overcurrent conditions during the pre-charge operation.

15. The integrated circuit of claim 1, wherein the fault detection circuit is further configured to detect at least one thermal shutdown condition when the integrated circuit temperature exceeds a predetermined threshold.

16. The integrated circuit of claim 1, wherein the integrated circuit is associated with Automotive Safety Integrity Level B (ASIL B).

17. The integrated circuit of claim 1, wherein the integrated circuit is configured for use in an electric vehicle or hybrid electric vehicle high voltage battery system.

18. The integrated circuit of claim 1, further comprising an isolated communication interface configured to transmit fault or status information to an external microcontroller.

19. An apparatus for pre-charging a battery system, comprising:
means for driving a switching device for selectively coupling a high voltage battery to a load capacitor;
means for sensing current flowing through the switching device during a pre-charge operation;
means for regulating the pre-charge current to a predetermined value;
means for identifying when the pre-charge operation is complete based on the sensed current or voltage across the load capacitor; and
means for detecting one or more fault conditions including at least one of gate open or short, desaturation of the switching device, undervoltage lockout, overcurrent, or thermal shutdown, and to provide a fault indication output.

20. A method of pre-charging a battery system, comprising:
driving a switching device for selectively coupling a high voltage battery to a load capacitor;
sensing current flowing through the switching device during a pre-charge operation;
regulating the pre-charge current to a predetermined value;
identifying when the pre-charge operation is complete based on the sensed current or voltage across the load capacitor; and
detecting one or more fault conditions including at least one of gate open or short, desaturation of the switching device, undervoltage lockout, overcurrent, or thermal shutdown, and to provide a fault indication output.
